(19) United States
(12) Patent Application Publication
(10) Pub. No.: US 2004/0018743 A1
(43) Pub. Date: Jan. 29, 2004

(54) Method for removing photoresist after metal layer etching in a semiconductor device

(76) Inventor: Jae-Pil Kim, Suwon-City (KR)

Correspondence Address: VOLENTINE FRANCOS, P.L.L.C., Suite 150, 12200 Sunrise Valley Drive, Reston, VA, 20191, US

(21) Appl. No.: 10/456,687

(22) Filed: Jun. 9, 2003

(30) Foreign Application Priority Data
Jul. 24, 2002 (KR) 2002-43476

(51) Int. Cl. H01L 21/302; H01L 21/461

(52) U.S. Cl. 438/725; 438/710

(57) ABSTRACT

A method of removing photoresist after metal layer etching in a semiconductor device prevents and minimizes polymer generation. The method includes stabilizing a photoresist deposited on top of a tungsten wiring layer under a pressure of about 9 Torr and a temperature of 245° C. through 255° C. under an N₂ atmosphere of 500 through 900 SCCM, in plasma equipment; and ashing the photoresist at a high frequency power of about 1000W, under a pressure of about 2.0 Torr and a temperature of 245° C. through 255° C. under an N₂ atmosphere of 500 through 750 SCCM and an O₂ atmosphere of about 4500 SCCM.

### BACKGROUND OF THE INVENTION

1. Field of the Invention

The present invention relates to fabrication of semiconductor devices, and more particularly to a method of removing a photoresist after metal layer etching in a semiconductor device.

A claim of priority is made to Korean Application No. 2002-43476 filed on Jul. 24, 2002, which is hereby incorporated by reference in its entirety for all purposes.

2. Description of the Related Art

In a semiconductor device fabricating process, a photolithographic process based on a photolithography technique is an essential procedure. Such a photolithographic process is largely classified into a photoresist deposition process, an exposure process, and a developing process. The photoresist deposition process involves coating a layer that is to be patterned with a photoresist. The exposure process involves irradiating light of comparative short wavelength onto a mask or reticle for exposure, after aligning wafers or substrates having the photoresist deposited thereon. The developing process involves developing the exposed photoresist with a developing solution to make a photoresist pattern. A subsequent etching process is divided into a layer etching process and an ashing process. The layer etching process etches the layer only, to expose a lower layer, by using the photoresist patterned through the photo process as an etch mask. The ashing process removes the photoresist used as the etch mask, after completion of the layer etching process.

The ashing process can be largely divided into a dry ashing and a wet ashing. The dry ashing process involves using an oxygen plasma discharge, ozone or excimer lamp etc. In the wet ashing process, a solution having a powerful oxidation reaction, e.g., a mixed solution of sulfuric acid and hydrogen peroxide, is used to remove the photoresist.

The dry ashing process is generally used when forming metal wires of a semiconductor device. For example, aluminum or tungsten wires are formed through a photo etch process and the photoresist used as the etch mask is then removed by a dry ashing process.

FIG. 1 shows a structure sequentially formed as including an interlayer dielectric film 12, barrier films 14, 16, and a tungsten wiring layer 18 formed on a substrate 10. The tungsten wiring layer 18 is anisotropically etched by using a photoresist 20 as an etch mask to obtain a pattern of desired shape, the photoresist 20 being formed on the tungsten wiring layer 18. The barrier films 14, 16 can be respectively made of Ti and TiN. After completion of the etching process, the dry ashing process of removing the photoresist 20 is chiefly executed within a chamber having an oxygen O₂ atmosphere.

However, a polymer generated in the etching process remains on the structure even after the ashing process is completed, as shown in FIG. 2. The polymer acts as an impurity when subsequently forming a dielectric film on top of the wiring layer or when forming another metallic wiring layer, and results in pollution on the layers and formation of an abnormal layer. Especially in a case where tungsten wires are more prominent than aluminum wires, the polymer generated within the etch equipment is harder. Therefore, removal of the polymer is very difficult.

Thus, in the conventional art, a stabilizing process is executed at a pressure of 2.5 Torr and a temperature of 275° C. for 12 seconds under an O₂ atmosphere of 3850 SCCM, in plasma equipment of medium density below about 10¹³cm³. After that, the ashing process is performed at a high frequency power of 1300 W, a pressure of 2.5 Torr and a temperature of 275° C. for 180 seconds, under an O₂ atmosphere of 3850 SCCM.

In such an ashing process, the polymer generated in the etching process of the tungsten wiring layer 18 is not completely removed, and the polymer residue a,b,c,d remains even after the ashing process. FIG. 6 is electron microscope sectional photograph showing that polymer of titanium oxide material still remains on the tungsten wiring layer 18 even after the above noted ashing process. Thus, it was conventionally required to further add one additional ashing process.

FIG. 3 is an electron microscope photograph showing an actual shape of photoresist residue. Such photoresist residue may cause a problem such as crack etc. in a dielectric film formed on top of the wiring layer or in following processes.

FIG. 4 is a sectional view of an electron photograph showing polymer adhering onto a corner portion of the tungsten wiring layer 18. This may cause a crack of the interlayer dielectric film formed in a following process. Thus, it is required to completely remove the polymer residues in the ashing process.

FIG. 5 provides an electron photograph showing a metal notching in the neighborhood of the tungsten wiring layer 18. This can also happen in the conventional ashing process, and becomes a cause of a short phenomenon between metal layers.

As described above, since polymer is not completely removed in the ashing process executed after etching of the tungsten wiring layer 18, such problems as cracking of an interlayer dielectric film, particle occurrence and shield drop etc. are caused. Such problems lower an operating rate of semiconductor fabricating process equipment, and cause various kinds of losses. These problems result in increasing the cost of semiconductor device fabrication.

### SUMMARY OF THE INVENTION

The present invention is therefore directed to a method of removing a photoresist after etching a metal layer of a semiconductor device, which substantially overcomes one or more of the problems due to the limitations and disadvantages of the background art.

To solve the above problems, it is an object of the present invention to provide a photoresist ashing method capable of preventing or minimizing generation of polymer after a metal layer etching.

It is another object of the present invention to provide an improved ashing method capable of effectively eliminating hard polymer in an ashing process for forming tungsten metal wires.

The above and other objects may be achieved by a method of removing a photoresist after metal layer etching in a semiconductor device, including stabilizing a photoresist deposited on top of a tungsten wiring layer at a pressure of 9 Torr and a temperature of 250° C. for 10 seconds under an N₂ atmosphere of 900 SCCM, in a plasma equipment of medium density below about 10¹³cm³; and ashing the photoresist at a high frequency power of 1000W, a pressure of 2.0 Torr and a temperature of 250° C. for 130 seconds under an N₂ atmosphere of 750 SCCM and an O₂ atmosphere of 4500 SCCM.

The method may further include supplying vapor for 40 seconds at a pressure of 2.0 Torr, a high frequency power of 1000W, and a temperature 250° C. under a vapor (H₂O) atmosphere of 450 SCCM, between the stabilizing and ashing processes.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIGS. 1 and 2 are sectional views for describing processing of metal wires according to a conventional technique;

FIGS. 3 through 6 are electron photographs showing various shapes of structures made according to the conventional techniques described with reference to FIGS. 1 and 2;

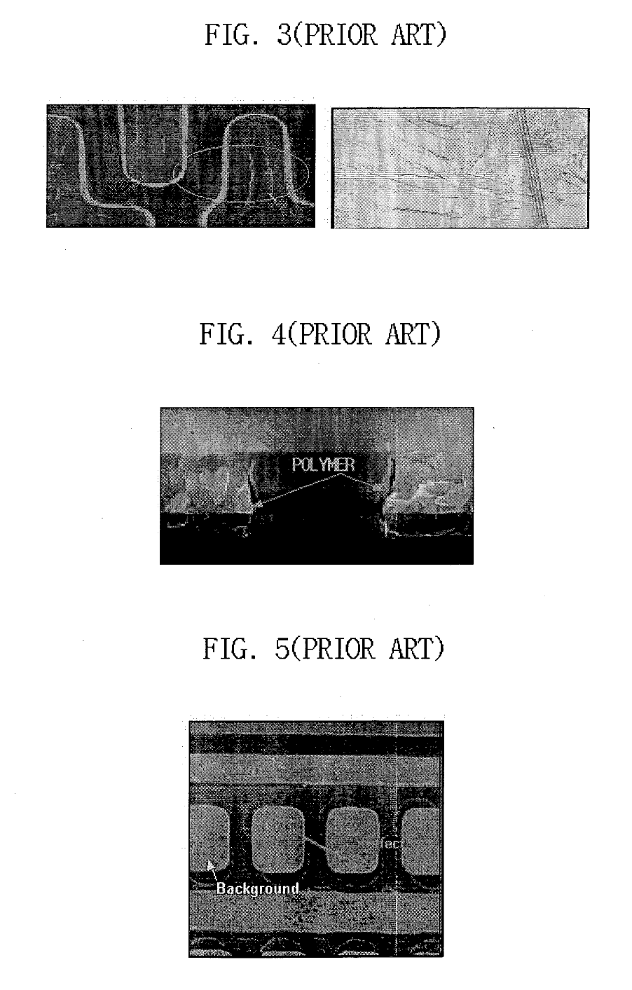

FIGS. 7 and 8 are sectional views for describing processing of a metallic wiring formation of a preferred embodiment of the present invention;

FIG. 9 is an electron photograph of a structure made using the process of the preferred embodiment; and

FIG. 10 is a flow chart illustrating process procedures of a preferred embodiment.

### DETAILED DESCRIPTION OF THE PREFERRED EMBODIMENTS

In accordance with preferred embodiments of the present invention, a method of removing a photoresist after etching a metal layer in a semiconductor device will be described with the same or similar reference characters and numbers for constructive elements that have the same or similar functions even on mutually different drawings.

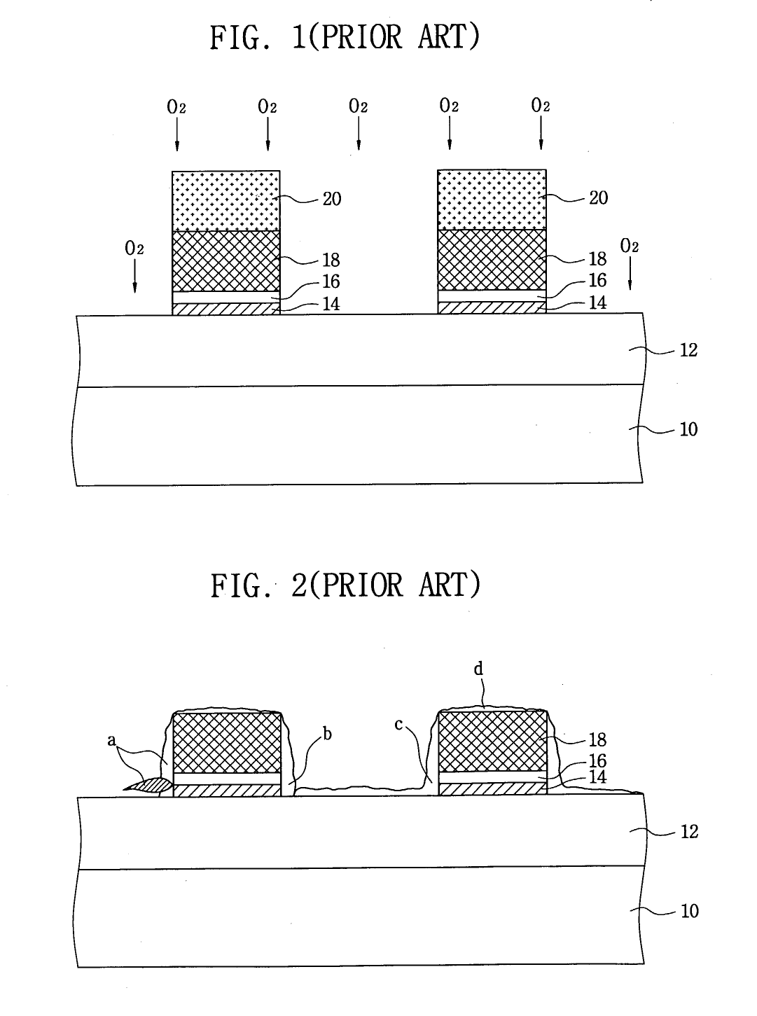

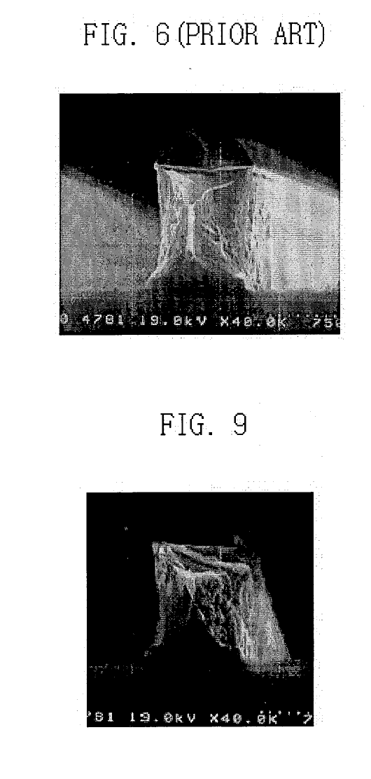

FIGS. 7 and 8 represent sectional views for describing processing of metal wiring formation of a preferred embodiment of the present invention. In FIG. 7, an interlayer dielectric film 12, barrier films 14 and 16 respectively of Ti and TiN for example, and a tungsten wiring layer 18 are sequentially formed on substrate 10. The tungsten wiring layer 18 is anisotropically etched using photoresist 20 as an etch mask, whereby photoresist 20 is formed on tungsten wiring layer 18. In FIG. 7, an ashing process of the resultant structure having an etch pattern like that in FIG. 1, is progressed under an N₂ atmosphere. As a result, polymer exists only on partial upper portions (e, f) of the tungsten wiring layer 18 as shown in

FIG. 8, and this can be removed cleanly in the following cleaning process.

In detail, the ashing process of FIG. 7 can be executed in plasma equipment of medium density in which the number of ions per unit is below about 10¹³cm³. Photoresist 20 deposited on the tungsten wiring layer 18 is passed through a stabilizing step at a pressure of about 9 Torr and a temperature of about 245° C. to 255° C., or about 250° C., for 10 seconds under an N₂ atmosphere of about 500-900 SCCM. This stabilizing step prevents oxidation of polymer. The stabilizing step minimizes generation of titanium oxide film by controlling oxidation of the titanium film 14 under the tungsten wiring layer 18.

After the stabilizing step, an ashing step is carried out on the photoresist at a high frequency power of about 1000W, a pressure of about 2.0 Torr and a temperature of about 245° C. to 255° C., or about 250° C., for 130 seconds under an N₂ atmosphere of about 500 to 750 SCCM and an O₂ atmosphere of about 4500 SCCM.

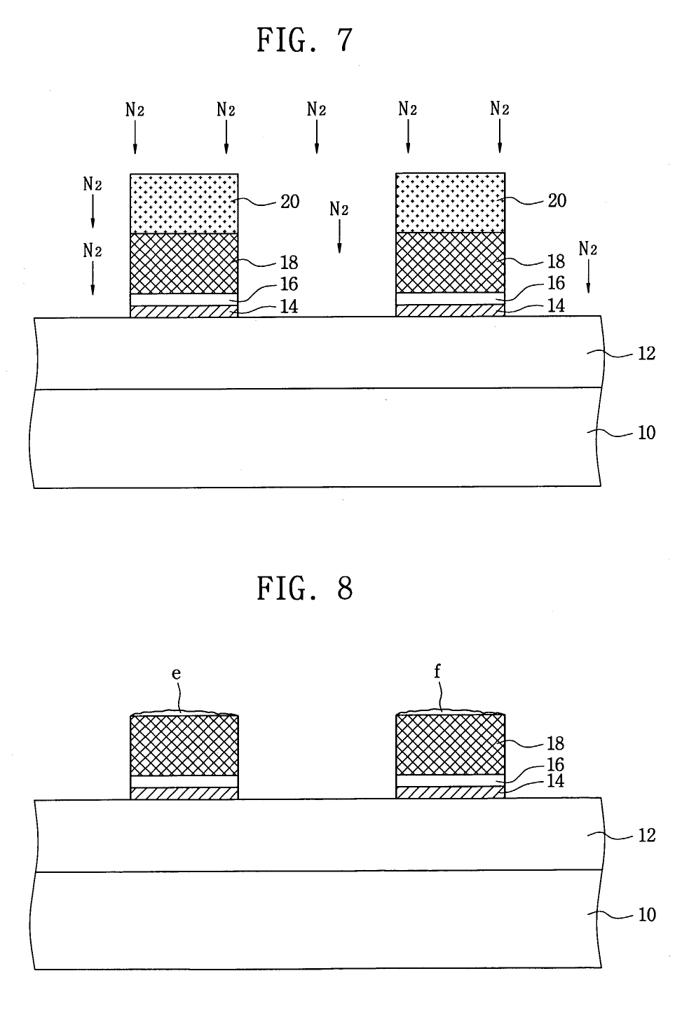

Also, in order to completely remove polymer and in order for a relaxation of the polymer between the stabilizing and ashing steps, a vapor supplying step may be carried out. The vapor supplying step involves supplying vapor for 40 seconds at a pressure of 2.0 Torr, a high frequency power of 1000W, and a temperature of 250° C. under a vapor (H₂O) atmosphere of 450 SCCM. By such processes, generation of polymer is controlled or minimized as shown in FIG. 9, which is an electron photograph of the resultant structure after the processes as described with respect to FIGS. 8 and 9 are carried out.

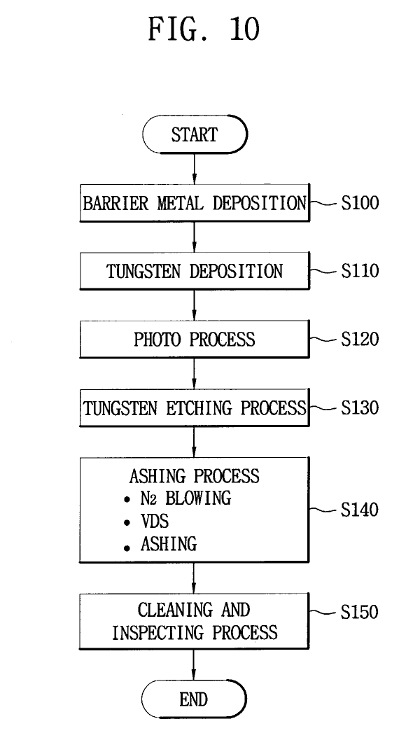

FIG. 10 is a flow chart of process procedures in accordance with the present invention. In the barrier metal deposition step S100, a Ti film 14 of about 900 Å and a TiN film 16 of about 600 Å are deposited on an interlayer dielectric film 12 of about 5500 Å. In the tungsten deposition step S110, a tungsten wiring layer 18 having a thickness of about 4400 Å is deposited. The structure of FIG. 7 is subsequently achieved after the photo process step S120 and the tungsten etching process step S130. The ashing process step S140 is then carried out under the previously described conditions on the structure of FIG. 7, to thus achieve the resultant structure of FIG. 8. Cleaning and inspecting process step S150 follows after completion of the ashing process.

In a case such that an ashing process is performed in plasma equipment of high density over about 10¹³cm³, the stabilizing step is carried out at a pressure of about 9 Torr and a temperature of 250° C. through 280° C. under an N₂ atmosphere of 500 through 900 SCCM. Further, the ashing process is carried out at a high frequency power of about 1000W, a pressure of about 2.0 Torr and a temperature of 250° C. through 280° C. under an N₂ atmosphere of 500 through 750 SCCM and an O₂ atmosphere of about 4500 SCCM. It should be understood that the temperature in such process equipment is an important factor, and should be optimally determined so as to prevent a titanium attack. It should be understood that the vapor supplying step may also be carried out in this embodiment between the stabilizing and ashing steps.

As afore-mentioned, in accordance with the present invention, a method of removing a photoresist after etching a metal layer of a semiconductor device has an advantage that generation of polymer can be prevented or minimized after a formation of tungsten metal wires. The polymer can therefore be reduced and removed. Accordingly, such conventional problems as cracking of a subsequently formed interlayer dielectric film, occurrence of particles, and a drop of yield etc. are avoided. That is, there is an advantage of curtailing fabrication costs of the semiconductor device.

It will be apparent to those skilled in the art that modifications and variations can be made in the present invention without deviating from the spirit or scope of the invention. For instance, conditions of the various processes can be varied within the scope of the invention. Thus, it is intended that the present invention cover any such modifications and variations of this invention provided they come within the scope of the appended claims and their equivalents.

What is claimed is:

1. A method of removing photoresist after metal layer etching of a semiconductor device, comprising:
stabilizing a photoresist deposited on a tungsten wiring layer, under a pressure of about 9 Torr and a temperature of 245° C. to 255° C. under an N₂ atmosphere of 500 to 900 SCCM, in plasma equipment; and
ashing the stabilized photoresist at a high frequency power of about 1000W, a pressure of about 2.0 Torr and a temperature of 245° C. to 255° C. under an N₂ atmosphere of 500 to 750 SCCM and an O₂ atmosphere of about 4500 SCCM.

2. The method of removing photoresist of claim 1, wherein the plasma equipment has a medium density below about 10¹³cm³ ions per unit.

3. The method of removing photoresist of claim 1, wherein the tungsten wiring layer is formed on a film comprised of an interlayer insulation film, a Ti film and a TiN film formed in sequence.

4. The method of removing photoresist of claim 1, further comprising supplying vapor for about 40 seconds at a high frequency power of about 1000W, under a pressure of about 2.0 Torr and a temperature of about 250° C. under a vapor(H₂O) atmosphere of about 450 SCCM, between said stabilizing and said ashing.

5. The method of removing photoresist of claim 1, wherein said stabilizing is performed for about 10 seconds.

6. The method of removing photoresist of claim 1, wherein said ashing is carried out for 130 seconds.

7. The method of removing photoresist of claim 1, wherein the temperature during said stabilizing is 250° C.

8. The method of removing photoresist of claim 1, wherein the temperature during said ashing is 250° C.

9. A method of removing photoresist after metal layer etching of a semiconductor device, comprising:
stabilizing a photoresist deposited on a tungsten wiring layer, under a pressure of about 9 Torr and a temperature of 250° C. to 280° C. under an N₂ atmosphere of 500 to 900 SCCM, in plasma equipment having a high density over about 10¹³cm³ ions per unit; and
ashing the stabilized photoresist at a high frequency power of about 1000W, a pressure of about 2.0 Torr and a temperature of 250° C. to 280° C. under an N₂ atmosphere of 500 to 750 SCCM and an O₂ atmosphere of about 4500 SCCM.

10. The method of claim 9, wherein the tungsten wiring layer is formed on a layer comprising a dielectric film of about 5500 Å, a Ti film of about 900 Å and a TiN film of 600 Å formed in sequence.

11. The method of removing photoresist of claim 9, further comprising supplying vapor for about 40 seconds at a high frequency power of about 1000W, under a pressure of about 2.0 Torr and a temperature of about 250° C. under a vapor(H₂O) atmosphere of about 450 SCCM, between said stabilizing and said ashing.
